(19) United States
(12) Patent Application Publication
(10) Pub. No.: US 2025/0183043 A1
(43) Pub. Date: Jun. 5, 2025

(54) SUBSTRATE PROCESSING METHOD AND SUBSTRATE PROCESSING APPARATUS

(71) Applicant: Tokyo Electron Limited, Tokyo (JP)

(72) Inventors: Nobuhiro TAKAHASHI, Nirasaki City (JP); Ayano HAGIWARA, Nirasaki City (JP); Tomoaki FUKUDA, Hillsboro, OR (US); Kento SUZUKI, Nirasaki City (JP)

(21) Appl. No.: 19/049,204

(22) Filed: Feb. 10, 2025

Related U.S. Application Data
(63) Continuation of application No. PCT/JP2023/042401, filed on Nov. 27, 2023.

(30) Foreign Application Priority Data
Dec. 9, 2022 (JP) 2022-197286

(51) Int. Cl. H01L 21/306; H01L 21/67

(52) U.S. Cl. CPC H01L 21/30604; H01L 21/67069

(57) ABSTRACT

A substrate processing method includes: etching a germanium-containing silicon film by supplying an etching gas for a germanium-containing silicon to a substrate on which the germanium-containing silicon film and a silicon film are formed; and subsequently, removing an etching residue of the germanium-containing silicon film while purging the etching gas from the substrate by supplying, to the substrate, a purge gas including a first processing gas containing fluorine and a second processing gas containing at least one of ammonia or amine.

### CROSS-REFERENCE TO RELATED APPLICATIONS

This application is a bypass continuation application of international application No. PCT/JP2023/042401 having an international filing date of Nov. 27, 2023 and designating the United States, the international application being based upon and claiming the benefit of priority from Japanese Patent Application No. 2022-197286, filed on Dec. 9, 2022, the entire contents of which are incorporated herein by reference.

### TECHNICAL FIELD

The present disclosure relates to a substrate processing method and a substrate processing apparatus.

### BACKGROUND

When manufacturing a semiconductor device, there is a case in which either a germanium-containing silicon (SiGe) film or a silicon (Si) film formed on a surface of a semiconductor wafer, which is a substrate (hereinafter referred to as “wafer”), is selectively etched. For example, Patent Document 1 discloses a technology for reducing a concentration of by-product gases to prevent damage to Si, when selectively etching SiGe with a fluorine-containing gas.

### PRIOR ART DOCUMENTS

### Patent Document

Patent Document 1: Japanese Patent Publication No. 7113711

### SUMMARY

According to one embodiment of the present disclosure, a substrate processing method includes: etching a germanium-containing silicon film by supplying an etching gas for a germanium-containing silicon to a substrate on which the germanium-containing silicon film and a silicon film are formed; and subsequently, removing an etching residue of the germanium-containing silicon film while purging the etching gas from the substrate by supplying, to the substrate, a purge gas including a first processing gas containing fluorine and a second processing gas containing at least one of ammonia or amine.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal side view illustrating an example of a structure to which a substrate processing method of the present disclosure is applied.

FIG. 2 is a first enlarged longitudinal cross-sectional view of the structure.

FIG. 3 is a second enlarged longitudinal cross-sectional view of the structure.

FIG. 4 is a third enlarged longitudinal cross-sectional view of the structure.

FIG. 5 is an explanatory diagram illustrating an example of a processing flow of the substrate processing method.

FIG. 6 is an explanatory diagram illustrating a concept of tuning a processing condition when removing etching residues.

FIG. 7 is a plan view illustrating an example of a substrate processing system for carrying out the substrate processing method.

FIG. 8 is a longitudinal side view illustrating an example of a processing module provided in the substrate processing system.

FIGS. 9A and 9B are enlarged photographs illustrating experimental results according to Example and Comparative Example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Example of Structure Formed by Substrate Processing of Present Disclosure>

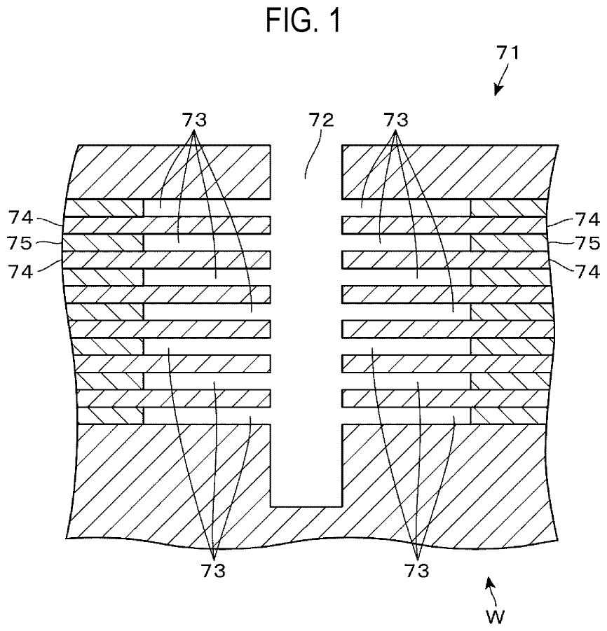

First, an example of a structure 71 formed on a wafer W by a substrate processing method of the present disclosure will be described with reference to FIG. 1. FIG. 1 is a longitudinal side view of the structure 71. A multilayer film in which multiple silicon-germanium (SiGe) films 75 and multiple silicon (Si) films 74 are alternately stacked one above another, is formed on the wafer W. In this multilayer film, each SiGe film 75 is structured to be sandwiched by the Si films 74 on both upper and lower surfaces thereof.

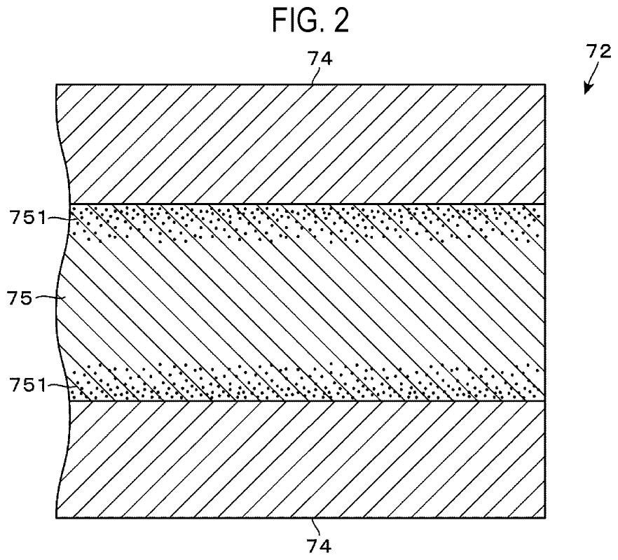

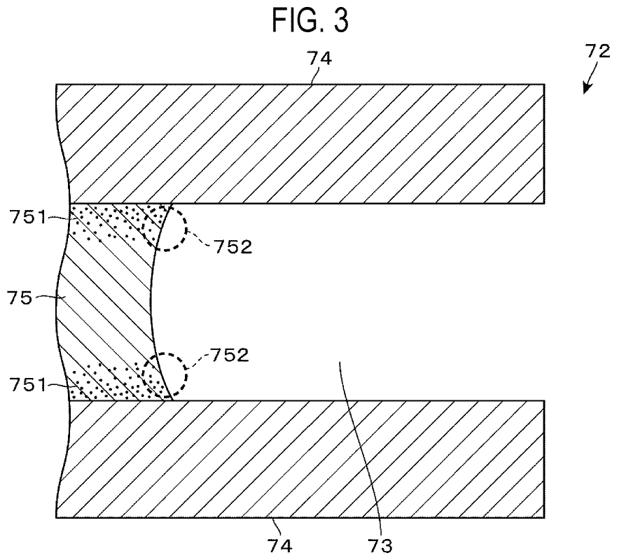

In the multilayer film, an opening 72 is formed in a vertical direction (direction intersecting with the multiple SiGe films 75 and the multiple Si films 74). As illustrated in the enlarged longitudinal cross-sectional view of FIG. 2, in the multilayer film, side end faces of the SiGe films 75 and the Si films 74 are exposed toward the opening 72. When an etching gas for etching SiGe is supplied via the opening 72, etching removal proceeds from the side end faces of the SiGe films 75 to form transversal holes along a plane of the wafer W (FIG. 3).

In this way, partial regions of the multiple SiGe films 75 with the side end faces exposed toward the opening 72 are etched away, respectively. As a result, as illustrated in FIG. 1, multiple recesses 73 may be formed, which open toward the opening 72 and are arranged at different height positions in the vertical direction.

As illustrated in the enlarged longitudinal cross-sectional view of FIG. 3, when viewed from the opening of the recess 73, longitudinal sidewalls of the recess 73 (upper and lower walls in the case of the transversal hole) where the etching process proceeds are formed by the Si films 74. Further, a back wall of the recess 73, corresponding to a position where the etching process stops, is formed by the SiGe film 75.

Here, in the structure 71 illustrated in FIG. 1, it is desirable for a tip of each recess 73 to have a rectangular shape in consideration of requirements of subsequent processing performed on the wafer W. However, the present inventors have found that the tip of the recess 73 formed by the above-described method may have a rounded shape (FIG. 3).

The following mechanism is considered the reason why the tip of the recess 73 is rounded. In the multilayer film with the structure 71 of FIG. 1, after the multiple Si films 74 and the multiple SiGe films 75 are alternately stacked one above another, an annealing process involving heating the wafer W may be performed. In such an annealed multilayer film, it is considered that Si atoms diffuse from the Si film 74 toward the SiGe film 75, and a mixed layer 751 with a high concentration of Si atoms is formed in the SiGe film 75 near an interface between the Si film 74 and the SiGe film 75 (FIG. 2). In addition, the mixed layer 751 is not limited to being formed by annealing the wafer W but may also be formed by a natural diffusion of Si atoms.

For example, the SiGe film 75 in this example is formed such that a concentration of Ge atoms falls within a range of 10 to 30 atm %, for example, 25 atm % (in this case, the concentration of Si atoms is approximately 75 atm %). On the other hand, in the mixed layer 751, the concentration of Ge atoms decreases to approximately 5 to 10 atm %. In other words, the mixed layer 751 is a region where the concentration of Si atoms increases to approximately 90 to 95 atm %.

Here, in the etching process of forming the recess 73, an etching gas for etching the SiGe film 75 is selected to be suitable for the etching removal of the SiGe film 75 with the aforementioned composition ratio (Si:Ge=75:25). However, the etching gas selected for the etching removal of the SiGe film 75 may exhibit a slower etching rate in the mixed layer 751 with a high concentration of Si atoms.

In this case, when comparing along a thickness direction of the SiGe film 75, the etching rate increases in the central region with a low concentration of Si atoms but decreases in the mixed layer 751 with a high concentration of Si atoms. It is considered that a difference in etching rate depending on the position inside the SiGe film 75 results in the phenomenon where the tip of the recess 73 formed by the etching process is rounded as illustrated in FIG. 3. Due to the relatively slower etching rate, SiGe remains at a boundary between the sidewalls and the back wall of the recess 73 (as indicated by dashed circles in FIG. 3). This remaining SiGe corresponds to an etching residue 752 in the present disclosure.

When the etching residue 752 is formed due to the high concentration of Si atoms, an etching gas suitable for the composition of the mixed layer 751 may be used to perform a separate processing for the etching removal of the etching residue 752. However, as illustrated in FIG. 3, the etching residue 752 remains in an extremely small region compared to the entire structure 71. Setting up an etching apparatus for forming the recess 73 or securing the time to transfer the wafer W toward the etching apparatus and perform the etching process in order to remove such a minute etching residue 752 is not realistic. Further, an etching gas capable of etching the etching residue 752 with a concentration of Si atoms of approximately 90 to 95 atm % may even damage the Si films 74 constituting the sidewalls of the recess 73 depending on the processing condition.

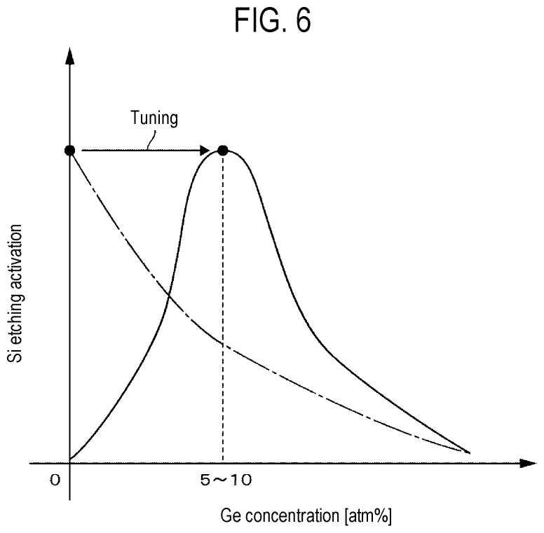

Therefore, in a substrate processing method of the present disclosure, after performing the etching process on the SiGe film 75 to form the recess 73, the removal of the etching residue 752 is performed by utilizing a timing of purging the etching gas. Hereinafter, details of the substrate processing method of the present disclosure, which is capable of forming the recess 73 with the tip of a shape that approximates a rectangle, will be described with reference to FIGS. 5 and 6.

### <Substrate Processing Method>

As illustrated in FIG. 5, the etching gas for SiGe is first supplied to the wafer W on which the multilayer film is formed. As a result, the etching gas enters the opening 72 of the multilayer film illustrated in FIG. 2, and the etching process of the SiGe film 75 proceeds from the side end face thereof exposed toward the opening 72 (Process P1: an operation of etching the SiGe film 75). The etching gas for SiGe may be at least one selected from the group consisting of a F₂ gas, a ClF₃ gas, a SF₆ gas, and an IF₇ gas. In the following example, a case in which the F₂ gas and the ClF₃ gas are used as the etching gas for SiGe, and an argon (Ar) gas and a nitrogen (N₂) gas are used as a carrier gas, will be described.

Supply flow rates of the gases may be exemplified as follows: the F₂ gas within a range of 1 to 100 sccm, the ClF₃ gas within a range of 0.1 to 2.0 sccm, the N₂ gas within a range of 50 to 200 sccm, and the Ar gas within a range of 10 to 100 sccm. Further, for example, a pressure applied during the etching process is set within a range of 1.3 to 40 Pa (10 to 300 mTorr), and a temperature of the wafer W is set within a range of −50 to 150 degrees C. Further, a duration required for the etching process may be exemplified as 50 seconds within a range of 5 to 120 seconds when forming the recess 73 with a depth of several nanometers. The etching gas may etch away the SiGe film 75 without activation such as plasma generation.

Through the above-described etching process, the recess 73 illustrated in FIG. 3 is formed, and the tip of the recess 73 has a rounded shape. Therefore, in the present disclosure, after completion of the etching of the SiGe film 75, a purge gas including a processing gas for etching away the etching residue 752 is supplied when purging the etching gas (Process P2 in FIG. 5: an operation of purging the etching gas and removing the etching residue 752). In addition, as a reference example, in a case in which the etching removal of the etching residue 752 is not performed, the N₂ gas and the Ar gas may be supplied at 100 sccm as the purge gas, respectively.

The processing gas included in the purge gas includes a first processing gas containing fluorine and a second processing gas containing at least one of ammonia or amine. The first processing gas containing fluorine may be at least one selected from the group consisting of the F₂ gas, the ClF₃ gas, the SF₆ gas, and the IF₇ gas.

Further, the second processing gas may be a NH₃ gas, an amine gas, or a mixed gas thereof. When the second processing gas contains amine, the amine may be selected from the group consisting of trimethylamine and butylamine.

In the following example, a case in which the F₂ gas is used as the first processing gas and the NH₃ gas is used as the second processing gas will be described.

Here, a mixed gas of the F₂ gas and the NH₃ gas may also be used as an etching gas for Si (as indicated by the one-dot dashed line in FIG. 6). Therefore, a processing condition may be tuned to purge the etching gas used in the etching process of the SiGe film 75 while etching away the etching residue 752, which is SiGe containing Ge atoms at a concentration of 5 to 10 atm % (as indicated by the solid line in FIG. 6).

In a first tuning, the process is performed under a lower pressure condition during a duration of Process P2 in FIG. 5 compared to that during a duration of Process P1. This pressure adjustment may facilitate the discharge of the etching gas supplied during Process P1 from the wafer W while suppressing damage to the Si film 74 by omitting the supply of a high-concentration processing gas. In a case in which the purge is performed after the etching process is performed on the wafer W inside a processing container 41 of a processing module 4 to be described later, a set value of a pressure change mechanism of the processing container 41 is set to a lower pressure. However, since the processing container 41 is supplied with the mixed gas of the F₂ gas and the NH₃ gas as described above, the actual internal pressure of the processing container 41 falls within a range of 0.0013 to 66.6 Pa (0.1 to 500 mTorr).

In a second tuning, a supply ratio of the processing gas is adjusted such that a ratio of the F₂ gas (the first processing gas) to the NH₃ gas (the second processing gas), which are contained in the purge gas, falls within a range of 15:1 to 5:1. In the etching gas for Si indicated by the one-dot dashed line in FIG. 6, the supply ratio is adjusted such that the ratio of the F₂ gas to the NH₃ gas is approximately 100:1. Thus, the damage to the Si film 74 is suppressed by reducing the supply ratio of the F₂ gas, which has a significant effect on Si etching.

The supply flow rates of the respective gases may be exemplified as follows: the F₂ gas within a range of 50 to 1,000 sccm and the NH₃ gas within a range of 1 to 100 sccm. Further, the temperature of the wafer W remains unchanged within a range of −50 to 150 degrees C. Thus, there is no activation such as plasmarization of the processing gas.

In a third tuning, Process P2 in FIG. 5 is performed during a shorter duration compared to Process P1. For example, as described above, a case in which the etching process of the SiGe film 75 is performed during a duration within a range of 5 to 120 seconds, while the purge process based on the supply of the mixed gas of the F₂ gas and the NH₃ gas is performed for 10 seconds within a range of 1 to 50 seconds may be exemplified. By completing the purge process based on the mixed gas of the F₂ gas and the NH₃ gas within a shorter duration compared to the etching process of the SiGe film 75, the minute etching residue 752 may be removed while suppressing the damage to the Si film 74.

As described above, various tunings are performed when supplying the first processing gas (the F₂ gas in the above-described example) and the second processing gas (the NH₃ gas in the above-described example) as the purge gas. With this process, the etching residue 752 of the mixed layer 751 may be removed such that the tip of the recess 73 has a desired etching shape that approximates a rectangle. Here, the expression “the tip of the recess 73 has a shape that approximates a rectangle” refers to making the back wall of the recess 73 flatter between the mixed layer 751 and the central region of the recess 73 by removing the etching residue 752.

In addition, all the above-described tunings performed in Process P2 are not necessarily essential. Only some of the tunings may be performed as long as the purge of the etching gas supplied during Process P1 is performed while removing the etching residue 752 to bring the tip of the recess 73 closer to a rectangle. Further, Process P2 may be performed under conditions other than the above-described tunings.

### <Substrate Processing System>

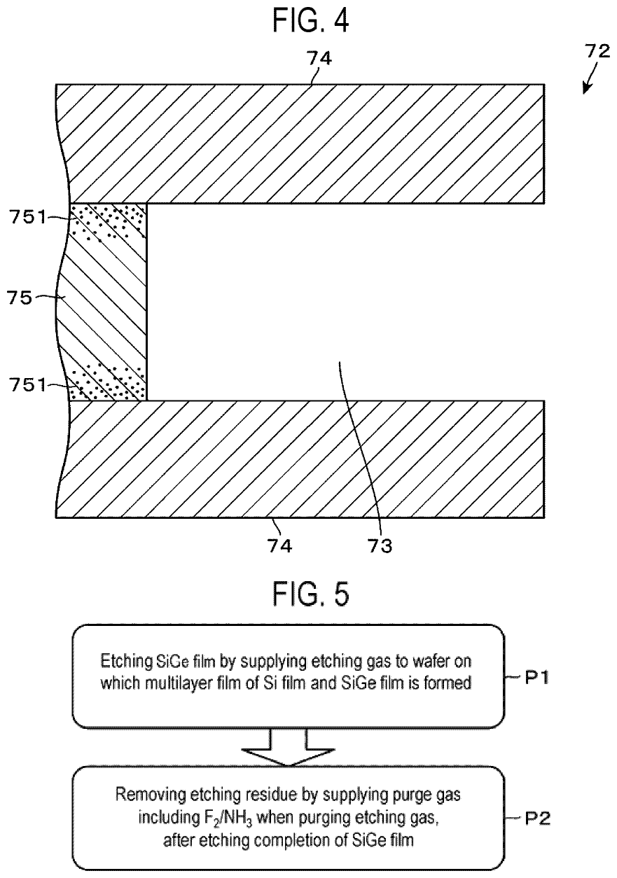

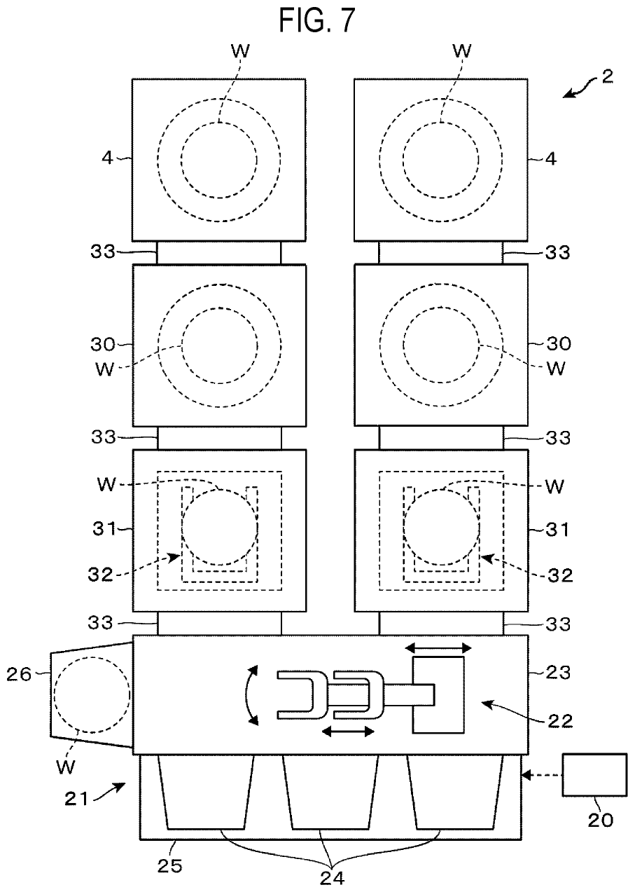

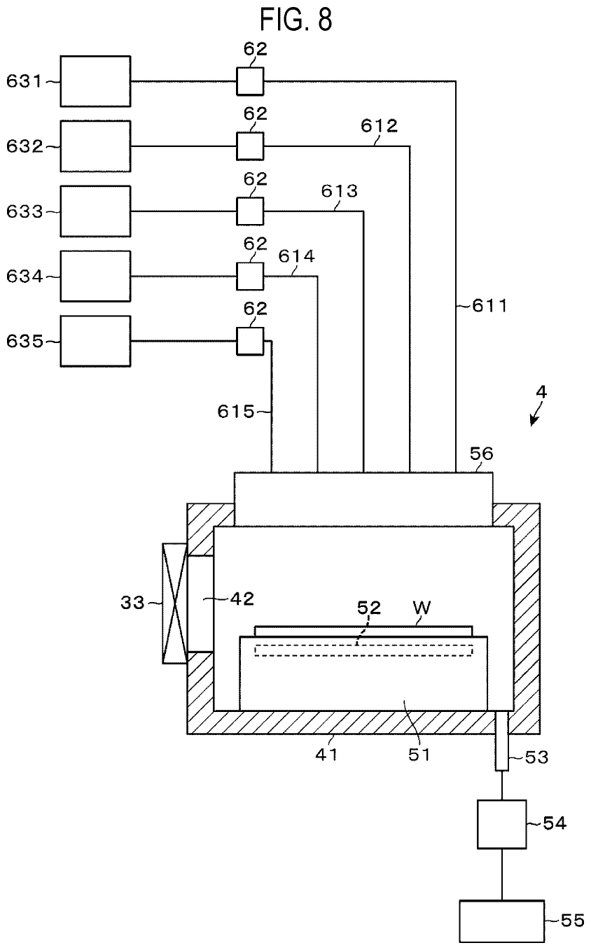

Next, an embodiment of a substrate processing apparatus for carrying out the substrate processing described with reference to FIGS. 1 to 6 will be described with reference to FIGS. 7 and 8. A substrate processing system 2 includes a loading/unloading section 21 for loading and unloading the wafer W, two load lock chambers 31 provided adjacent to the loading/unloading section 21, two thermal processing modules 30 provided respectively adjacent to the two load lock chambers 31, and two processing modules 4 provided respectively adjacent to the two thermal processing modules 30. The processing module 4 corresponds to the substrate processing apparatus of the present disclosure.

The loading/unloading section 21 includes an atmospheric-pressure transfer chamber 23, which is provided with a first substrate transfer mechanism 22 and is kept in an atmospheric atmosphere, and a carrier stage 25, which is provided on a side of the atmospheric-pressure transfer chamber 23 and on which a carrier 24 accommodating the wafer W therein is placed. In FIG. 7, reference numeral 26 denotes an aligner chamber provided adjacent to the atmospheric-pressure transfer chamber 23. In the aligner chamber 26, an eccentricity of the wafer W which is being rotated is optically measured, and positioning of the wafer W with respect to the first substrate transfer mechanism 22 is performed. The first substrate transfer mechanism 22 transfers the wafer W between the carrier 24 on the carrier stage 25, the aligner chamber 26, and the load lock chamber 31.

Each of the load lock chamber 31s includes a second substrate transfer mechanism 32 having, for example, a multi-joint arm structure. The second substrate transfer mechanism 32 transfers the wafer W between the load lock chamber 31, the thermal processing module 30, and the processing module 4. An interior of a processing container constituting the processing module 4 is kept in a vacuum atmosphere. An interior of the load lock chamber 31 is switched between the atmospheric atmosphere and the vacuum atmosphere such that the wafer W is transferred between the interior of the processing container kept in the vacuum atmosphere and the atmospheric-pressure transfer chamber 23.

In FIG. 7, reference numeral 33 denotes gate valves that are capable of being opened/closed. The gate valves 33 are provided between the atmospheric-pressure transfer chamber 23 and the load lock chamber 31, between the load lock chamber 31 and the thermal processing module 30, and between the thermal processing module 30 and the processing module 4, respectively. The thermal processing module 30 includes the aforementioned processing container, an exhaust mechanism for exhausting the interior of the processing container to create a vacuum atmosphere, a stage provided inside the processing container and capable of heating the wafer W placed thereon, and the like. The thermal processing module 30 is configured to execute a process of heating the wafer W to sublime reaction by-products.

The processing module 4, which is the substrate processing apparatus of the present disclosure, will be described with reference to the longitudinal side view of FIG. 8. The processing module 4 performs Processes P1 and P2 described above. In FIG. 8, reference numeral 41 denotes the processing container constituting the processing module 4. Further, in FIG. 8, reference numeral 42 denotes a transfer port for the wafer W, which is opened in the sidewall of the processing container 41. The transfer port 44 is opened or closed by the gate valve 33. A stage 51 on which the wafer W is placed is provided inside the processing container 41. The stage 51 is provided with lift pins (not illustrated). The wafer W is transferred between the stage 51 and the second substrate transfer mechanism 32 by the lift pins.

A temperature adjuster 52 is embedded in the stage 51. The wafer W placed on the stage 51 is heated to the aforementioned temperature. The temperature adjuster 52 is configured as a flow path which constitutes a portion of a circulation path through which a temperature adjustment fluid such as water flows. The temperature of the wafer W is adjusted by heat exchange with the fluid. However, the temperature adjuster 52 is not limited to such a fluid flow path, and may be constituted with, for example, a heater for performing resistance heating.

Further, one end of an exhaust pipe 53 is opened inward of the processing container 41, and the other end thereof is connected to an exhaust mechanism 55, which is constituted with, for example, a vacuum pump, via a valve 54 as a pressure change mechanism. An internal pressure of the processing container 41 is adjusted in the aforementioned range by adjusting an opening degree of the valve 54. In this state, the process is performed.

A gas shower head 56, which is a processing gas supply mechanism, is provided in an upper portion of the interior of the processing container 41 so as to face the stage 51. The gas shower head 56 is connected to downstream sides of gas supply paths 611 to 615. Upstream sides of the gas supply paths 611 to 615 are connected respectively to gas sources 631 to 635 via respective flow rate adjusters 62. Each flow rate adjuster 62 includes a valve and a mass flow controller. The supply and cutoff of gases from the gas sources 631 to 635 to the downstream sides are performed by opening and closing the valves included in the flow rate adjusters 62.

The gas sources 631, 632, 633, 634 and 635 supply the F₂ gas, the ClF₃ gas, the NH₃ gas, the Ar gas, and the N₂ gas, respectively. Thus, the F₂ gas, the ClF₃ gas, the NH₃ gas, the Ar gas, and the N₂ gas may be supplied into the processing container 41 from the gas shower head 56, respectively. The Ar gas and the N₂ gas are supplied as carrier gases into the processing container 41, together with the F₂ gas and the ClF₃ gas as etching gases. Further, the F₂ gas and the NH₃ gas are supplied as purge gases into the processing container 41.

Further, as illustrated in FIG. 7, the substrate processing system 2 includes a controller 20, which is a computer. The controller 20 includes a program, a memory, and a CPU. The program incorporates instructions (each step) for executing the above-described processing and transfer of the wafer W. This program is stored in a non-transitory computer-readable storage medium such as a compact disc, a hard disc, a magneto-optical disc, a DVD, or a non-volatile memory, and is installed in the controller 20. The controller 20 outputs control signals for controlling operations of individual constituent elements of the substrate processing system 2 using the program. Specifically, the operation of the processing module 4, the operation of the thermal processing module 30, the operations of the first substrate transfer mechanism 22 and the second substrate transfer mechanism 32, and the operation of the aligner chamber 26 are controlled by the respective control signals. Examples of the operation of the processing module 4 may include the adjustment of the temperature of the fluid supplied to the stage 51, the supply and cutoff of each gas from the gas shower head 56, and the adjustment of the exhaust flow rate by the valve 54.

### <Operation of Substrate Processing System>

The operation of processing the wafer W in the substrate processing system 2 will be described. As described with reference to FIG. 1, the carrier 24 storing the wafer W in which the multilayer film and the opening 72 are formed, is placed on the carrier stage 25. Subsequently, the wafer W is transferred in the order of the atmospheric-pressure transfer chamber 23, the aligner chamber 26, the atmospheric-pressure transfer chamber 23, and the load lock chamber 31, and lastly is transferred to the processing module 4 via the thermal processing module 30. Thereafter, Process P1 in FIG. 5 is performed. In Process P1, a partial region of the SiGe film 75 is etched away to form the recess 73. Thereafter, Process P2 in FIG. 5 is performed. In Process P2, the etching gas for SiGe is purged, and the etching residue 752 is removed with the mixed gas of the F₂ gas and the NH₃ gas as the purge gas. By these Processes, the tip of the recess 73 may have a shape that approximates a rectangle.

Thereafter, the wafer W is transferred from the processing module 4 in the order of the thermal processing module 30, the load lock chamber 31, and the atmospheric-pressure transfer chamber 23, and lastly is returned to the carrier 24.

### <Variations>

Here, an object to which the substrate processing method of the present disclosure is applied is not limited to the wafer W having the structure 71 illustrated in FIG. 1. For example, the substrate processing method of the present disclosure may be applied to a wafer W in which a SiGe region is sandwiched between Si regions when viewed from above. In this case, the etching gas for SiGe may be supplied to the surface of the wafer W to etch SiGe so that a downwardly-extending recess is formed in the wafer W. Thereafter, like the above-described embodiment, the etching residue 752 is removed with the purge gas including the first processing gas containing fluorine and the second processing gas containing at least one of ammonia or amine so that the tip of the recess has a shape that approximates a rectangle.

In addition, the substrate processing method of the present disclosure is not limited to being applied when forming the recess. For example, the technology of the present disclosure may be applied to pattern the SiGe film formed on the upper surface of the Si film. In this case, after a patterned resist film or a sacrificial film is formed on the upper surface of the SiGe film, the etching gas for SiGe is supplied to etch the SiGe. Thereafter, an etching residue layer remaining on a bottom surface of the patterned SiGe film may be removed with the purge gas containing the first processing gas and the second processing gas.

Further, the completion of the purge process with the purge gas including the first processing gas containing fluorine and the second processing gas containing at least one of ammonia or amine is not essential. After performing the purge process, another gas (for example, an inert gas such as a N₂ gas or an Ar gas) may be additionally supplied to continue the purge process. In contrast, an initial purge process using an inert gas may be performed, and subsequently, the etching residue 752 may be removed with the purge gas including the first processing gas and the second processing gas.

According to the present disclosure in some embodiments, it is possible to remove an etching residue of a germanium-containing silicon film to form a desired etching shape.

The embodiments disclosed herein should be considered as illustrative and not restrictive in all respects. The above embodiments may be omitted, replaced, or modified in various ways without departing from the scope and spirit of the appended claims.

### Examples

### (Experiment)

After supplying the etching gas for SiGe to the wafer W in which the multilayer film composed of the SiGe films 75 and the Si films 74 is formed to form the recess 73, the type of purge gas supplied to the wafer W was changed, and the shape of the tip of the recess 73 was confirmed.

### A. Experimental Condition

### Example

The recess 73 with a depth of 40 nm was formed under a range condition set in the above-described range. Thereafter, a set pressure value was changed to the pressure of the first tuning described above, and the purge process was performed by supplying the F₂ gas at a flow rate of 600 sccm and the NH₃ gas at a flow rate of 40 sccm for 10 seconds. A longitudinal cross-sectional shape of the wafer W subjected to these processes was observed using an electron microscope.

### Comparative Example

In Comparative Example, a process similar to Example was performed except that the N₂ gas and the Ar gas were supplied as the purge gases at a flow rate of 200 sccm and a flow rate of 200 sccm, respectively.

### B. Experiment Results

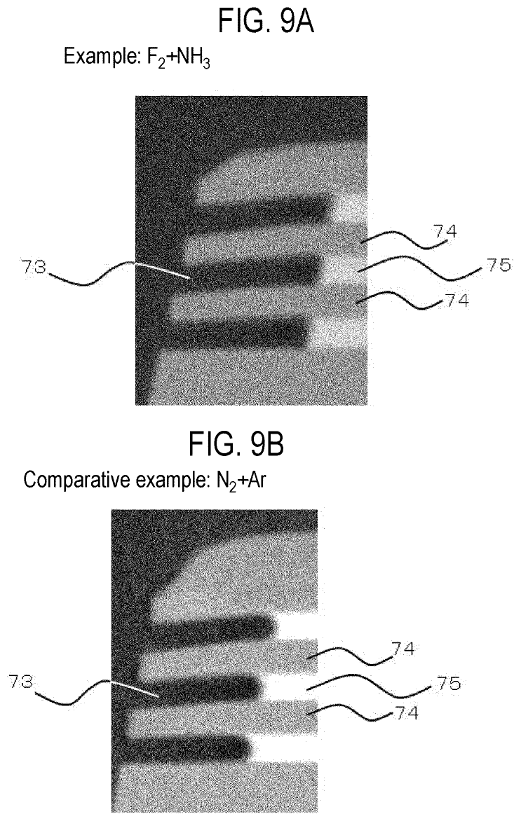

FIG. 9A illustrates an enlarged photograph relating to Example, and FIG. 9B illustrates an enlarged photograph relating to Comparative Example. According to these photographs, in Example, the influence of the etching residue 752 was not observed, and the recess 73 having a tip of a rectangular shape was obtained. On the other hand, in Comparative Example, the tip of the recess 73 had a rounded shape. This is thought to be due to the fact that the etching residue 752 is formed in the mixed layer 751, as described above with reference to FIG. 3.

It was confirmed from the above experimental results that the tip of the recess 73 may be shaped closer to a rectangle by supplying the purge gas composed of the F₂ gas (the first processing gas) and the NH₃ gas (the second processing gas) after etching the SiGe film 75 to form the recess 73.

What is claimed is:

1. A substrate processing method, comprising:
etching a germanium-containing silicon film by supplying an etching gas for a germanium-containing silicon to a substrate on which the germanium-containing silicon film and a silicon film are formed; and
subsequently, removing an etching residue of the germanium-containing silicon film while purging the etching gas from the substrate by supplying, to the substrate, a purge gas including a first processing gas containing fluorine and a second processing gas containing at least one of ammonia or amine.

2. The substrate processing method of claim 1, wherein the etching residue is formed in a region where a silicon concentration has increased due to diffusion of silicon from the silicon film to the germanium-containing silicon film, causing a decrease in an etching rate by the etching gas for the germanium-containing silicon.

3. The substrate processing method of claim 1, wherein a multilayer film in which the silicon film is stacked to sandwich the germanium-containing silicon film is formed on the substrate,
wherein in the etching the germanium-containing silicon film, the germanium-containing silicon film is etched from an end side of the multilayer film to form a recess having a sidewall of the silicon film and a back wall of the germanium-containing silicon film, and
wherein in the removing the etching residue, the etching residue remaining at a boundary between the sidewall and the back wall of the recess is removed so that a cross-sectional shape of the recess becomes a rectangle.

4. The substrate processing method of claim 1, wherein the removing the etching residue is performed under a lower pressure condition compared to the etching the germanium-containing silicon film.

5. The substrate processing method of claim 1, wherein a ratio of the first processing gas to the second processing gas, which are included in the purge gas, falls within a range of 15:1 to 5:1.

6. The substrate processing method of claim 1, wherein the removing the etching residue is performed within a shorter duration compared to the etching the germanium-containing silicon film.

7. The substrate processing method of claim 1, wherein the etching gas for the germanium-containing silicon is at least one selected from a group consisting of a F₂ gas, a ClF₃ gas, a SF₆ gas, and an IF₇ gas.

8. The substrate processing method of claim 1, wherein the first processing gas is at least one selected from a group consisting of a F₂ gas, a ClF₃ gas, a SF₆ gas, and an IF₇ gas.

9. The substrate processing method of claim 1, wherein when the second processing gas contains amine, the amine is selected from a group consisting of trimethylamine and butylamine.

10. A substrate processing apparatus, comprising:
a processing container in which a substrate on which a germanium-containing silicon film and a silicon film are formed is accommodated;
an etching gas supply mechanism configured to supply an etching gas for a germanium-containing silicon into the processing container;
a purge gas supply mechanism configured to supply a purge gas including a first processing gas containing fluorine and a second processing gas containing at least one of ammonia or amine into the processing container; and
a controller configured to output a control signal to perform:
etching the germanium-containing silicon film by supplying the etching gas into the processing container; and
subsequently, removing an etching residue of the germanium-containing silicon film while purging the etching gas from the processing container by supplying the purge gas.
